(19) United States
(12) Patent Application Publication
(10) Pub. No.: US 2025/0192726 A1
(43) Pub. Date: Jun. 12, 2025

(54) CIRCUIT DEVICE AND DOHERTY AMPLIFIER

(71) Applicant: SUMITOMO ELECTRIC DEVICE INNOVATIONS, INC., Yokohama-shi (JP)

(72) Inventors: Kohei MATSUMOTO, Yokohama-shi (JP); Norihiro YOSHIMURA, Yokohama-shi (JP); Osamu ANEGAWA, Yokohama-shi (JP)

(73) Assignee: SUMITOMO ELECTRIC DEVICE INNOVATIONS, INC., Yokohama-shi (JP)

(21) Appl. No.: 18/888,689

(22) Filed: Sep. 18, 2024

(30) Foreign Application Priority Data
Dec. 7, 2023 (JP) 2023-206861

(51) Int. Cl. H03F 1/02; H01L 23/66; H03F 1/56

(52) U.S. Cl. CPC H03F 1/0288; H01L 23/66; H03F 1/56; H01L 2223/6611; H01L 2223/6655

(57) ABSTRACT

This circuit device is a circuit device for impedance matching with a transistor. The circuit device includes a substrate having a main surface and a matching circuit provided on the main surface and connected to an input terminal or an output terminal of the transistor to perform impedance matching with the transistor. The matching circuit has a bonding wire that serves as an internal wiring of the matching circuit and is completed on the main surface.

### REFERENCE TO RELATED APPLICATION

This application is based upon and claims the benefit of priority from Japanese Patent Application No. 2023-206861, filed on Dec. 7, 2023, the entire contents of which are incorporated herein by reference.

### TECHNICAL FIELD

The present disclosure relates to a circuit device and a Doherty amplifier.

### BACKGROUND OF THE INVENTION

Japanese Unexamined Patent Publication No. 2019-092009 discloses a Doherty amplifier including a main amplifier and a peak amplifier. The main amplifier and the peak amplifier have matching circuits.

### SUMMARY OF THE INVENTION

A circuit device according to the present disclosure is a circuit device for impedance matching with a transistor and includes: a substrate having a main surface; and a matching circuit provided on the main surface and connected to an input terminal or an output terminal of the transistor to perform impedance matching with the transistor. The matching circuit has a bonding wire that serves as an internal wiring of the matching circuit and is completed on the main surface.

### BRIEF DESCRIPTION OF THE DRAWINGS

FIG. 1 is a perspective view showing a Doherty amplifier according to one embodiment of the present disclosure.

FIG. 2 is a perspective view showing a main part of the Doherty amplifier.

FIG. 3 is a plan view showing the main part of the Doherty amplifier.

FIG. 4 is a circuit diagram of a main amplifier.

FIG. 5 is a plan view of a circuit device.

FIG. 6 is a perspective view of the circuit device.

FIG. 7 is a plan view of a circuit device.

FIG. 8 is a plan view showing a circuit device according to a comparative example.

FIG. 9 is a plan view showing a circuit device according to the comparative example.

FIG. 10 is a diagram showing a simplified configuration of a main amplifier of a Doherty amplifier including the circuit devices.

FIG. 11A-11B is a Smith chart used in designing a main amplifier and a peak amplifier.

FIG. 12 is a plan view showing a Doherty amplifier.

FIG. 13A-13F is a diagram schematically showing a variation of a relationship between an extending direction of a bonding wire of a circuit device of a main amplifier and an extending direction of a bonding wire of a circuit device of a peak amplifier.

FIG. 14 is a side view of a bonding wire.

### DETAILED DESCRIPTION

A circuit device for impedance matching that is connected to an input terminal or an output terminal of a transistor is known. This circuit device is constituted by circuit elements, such as filters and delay lines, formed on a substrate. The circuit device further includes a transmission line in each of the circuit elements and between the circuit devices.

In such a circuit device, the length of the transmission line is set in consideration of impedance matching. Depending on the impedance of the transistor, the transmission line is long. In that case, a large area is required on the substrate to lay out the transmission line, which causes an increase in size of the circuit device.

An object of the present disclosure is to provide a circuit device for impedance matching that can be made smaller in size even in a case in which a transmission line is long, and a Doherty amplifier including the circuit device.

### Description of Embodiment of the Present Disclosure

First, the content of an embodiment of the present disclosure will be listed and described. [1] A circuit device according to one aspect of the present disclosure is a circuit device for impedance matching with a transistor and includes: a substrate having a main surface; and a matching circuit provided on the main surface and connected to an input terminal or an output terminal of the transistor to perform impedance matching with the transistor. The matching circuit has a bonding wire that serves as an internal wiring of the matching circuit and is completed on the main surface.

Compared to the transmission line, the bonding wire can be disposed close to other elements that constitute the matching circuit (other portions of the transmission line, the capacitor, and the like) in a planar view, or can straddle the other elements. Therefore, even in a case in which the transmission line is long, the area required for laying out the transmission line can be reduced by replacing a part of the transmission line with the bonding wire. Therefore, according to this circuit device, the circuit device can be made smaller in size even in a case in which when the transmission line is long.

[2] In the circuit device according to [1] above, the bonding wire may straddle other elements included in the matching circuit. In this case, since the space above the other elements is utilized, the area for laying out the transmission line can be made smaller, and the circuit device can be made even smaller in size.

[3] In the circuit device according to [1] or [2] above, the matching circuit may have a filter, and the bonding wire may constitute a part of the filter. In this case, since the area on the main surface required for the filter can be reduced, the circuit device can be made smaller in size.

[4] In the circuit device according to [3] above, the filter may be a low-pass filter, a first end of the bonding wire may be connected to an input end of the low-pass filter, and a second end of the bonding wire may be connected to an output end of the low-pass filter.

[5] In the circuit device according to [3] above, the filter may be a high-pass filter, and the bonding wire may constitute a part of a bias wiring provided in the high-pass filter.

[6] In the circuit device according to any one of [1] to [5] above, the matching circuit may have a delay line, and the bonding wire may constitute a part of the delay line. In this case, since the area on the main surface required for the delay line can be reduced, the circuit device can be made smaller in size.

[7] In the circuit device according to any one of [1] to [6] above, the matching circuit may have a transmission line, and the bonding wire may be connected in series with the transmission line. In this way, by connecting the bonding wire in series with the transmission line, it is possible to replace another transmission line connected to the transmission line, that is, a part of the transmission line, with the bonding wire. Therefore, the area required for laying out the transmission line can be reduced.

[8] A Doherty amplifier according to one aspect of the present disclosure is a Doherty amplifier including a main amplifier and a peak amplifier. The main amplifier has a first circuit device which is the circuit device according to any one of [1] to [7]. The peak amplifier has a second circuit device which is the circuit device according to any one of [1] to [7]. The first circuit device is disposed side by side with the second circuit device in a first direction. An extending direction of the bonding wire of the first circuit device when viewed in a normal direction of the main surface intersects with an extending direction of the bonding wire of the second circuit device when viewed in the normal direction. In this case, the crosstalk between the first circuit device and the second circuit device can be reduced.

[9] In the Doherty amplifier according to [8] above, one bonding wire of the bonding wire of the first circuit device and the bonding wire of the second circuit device may be along the first direction. Another bonding wire of the bonding wire of the first circuit device and the bonding wire of the second circuit device may be along a second direction intersecting with the first direction. The one bonding wire may include a first portion close to the another bonding wire and a second portion further away from the another bonding wire than the first portion. An inclination angle of the second portion with respect to the main surface may be greater than an inclination angle of the first portion with respect to the main surface. In this case, the crosstalk between the first circuit device and the second circuit device can be further reduced.

### Details of Embodiments of the Present Disclosure

Specific examples of the circuit device and the Doherty amplifier of the present disclosure will be described below with reference to the drawings. The present invention is not limited to these examples, but is defined by the scope of the claims, and is intended to include meanings equivalent to the scope of the claims and all modifications within the scope. In the following description, the same elements will be denoted by the same reference signs in the description of the drawings, without redundant description.

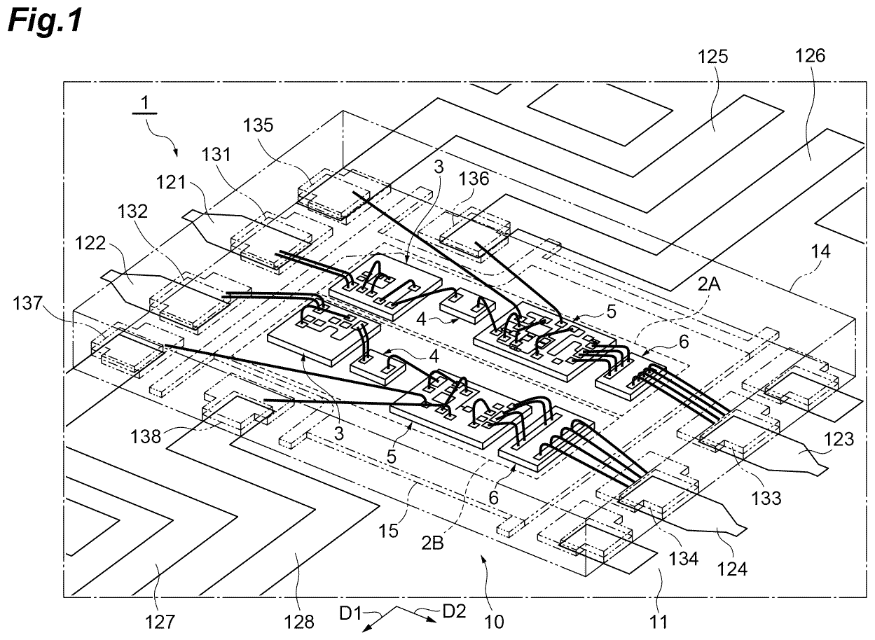

FIG. 1 is a perspective view showing a Doherty amplifier 1 according to one embodiment of the present disclosure. The Doherty amplifier 1 of the present embodiment includes a base 10 having a main surface 11, a reference potential pattern 15 which is a metal film provided on the main surface 11 of the base 10, and a main amplifier 2A and a peak amplifier 2B provided on the reference potential pattern 15. In addition, the Doherty amplifier 1 includes pads 131 to 138 and wirings 121 to 128. The pads 131 to 138 are provided around the reference potential pattern 15. The wirings 121 to 128 are metal films provided on the main surface 11 of the base 10 and extend from areas between the pads 131 to 138 and the main surface 11 of the base 10 toward the outside of the Doherty amplifier 1. The wirings 121 to 128 are conductively joined to the pads 131 to 138, respectively. On the main surface 11 of the base 10, the main amplifier 2A, the peak amplifier 2B, the reference potential pattern 15, and the pads 131 to 138 are covered and protected by a resin body 14.

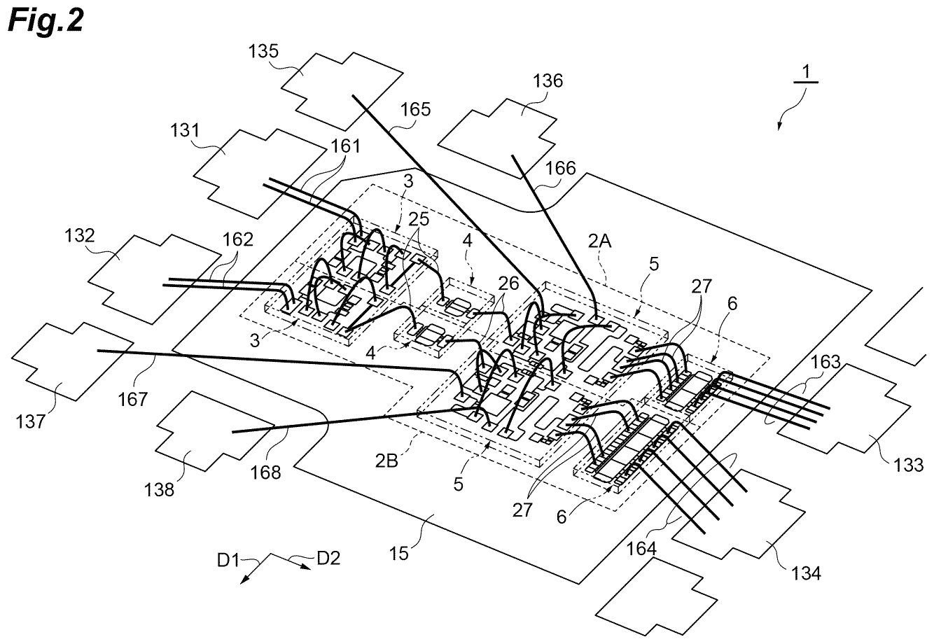

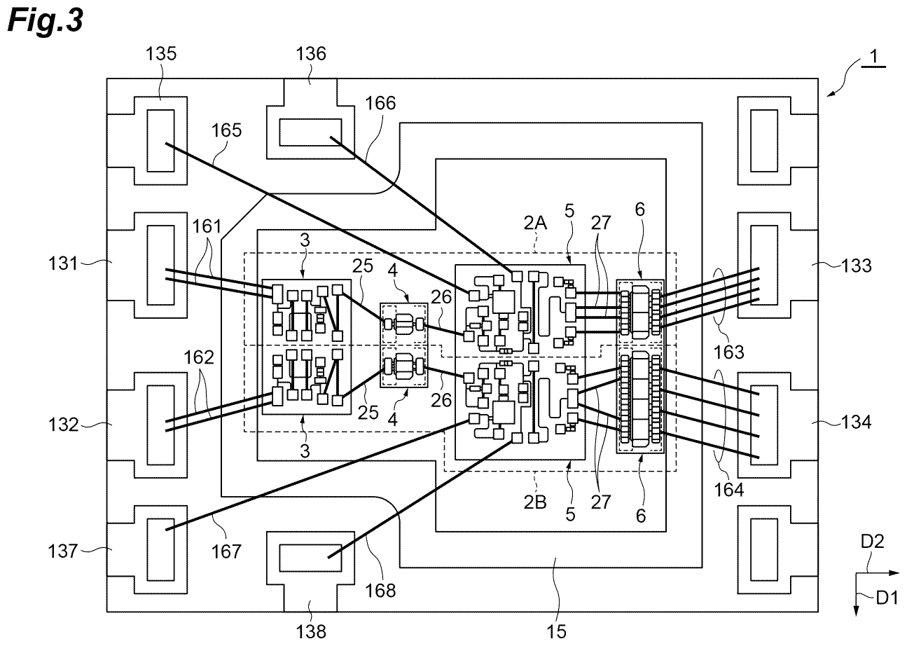

FIG. 2 is a perspective view showing a main part of the Doherty amplifier 1. FIG. 3 is a plan view showing the main part of the Doherty amplifier 1. As shown in FIGS. 1 to 3, the main amplifier 2A and the peak amplifier 2B are disposed side by side in a direction D1 (a first direction). Each of the main amplifier 2A and the peak amplifier 2B includes a circuit device (an integrated passive device, IPD) 3, a transistor 4, a circuit device (IPD) 5, and a transistor 6. The circuit device 3, the transistor 4, the circuit device 5, and the transistor 6 are disposed side by side in that order in a direction D2 (a second direction) intersecting with the direction D1. In the example shown in FIG. 1, the elements of the main amplifier 2A (the circuit device 3, the transistor 4, the circuit device 5, and the transistor 6) and the elements of the peak amplifier 2B (the circuit device 3, the transistor 4, the circuit device 5, and the transistor 6) are disposed away from each other. On the other hand, in the example shown in FIGS. 2 and 3, the elements of the main amplifier 2A and the elements of the peak amplifier 2B are disposed close to each other (or on the same substrate). The arrangement relationship between the elements of the main amplifier 2A and the elements of the peak amplifier 2B may be any of these.

The circuit device 3 is a circuit for matching the input impedance of the transistor 4. The circuit device 3 of the main amplifier 2A is electrically connected to the pad 131 via a bonding wire 161. The circuit device 3 of the main amplifier 2A receives a first signal through the wiring 121. The circuit device 3 of the peak amplifier 2B is electrically connected to the pad 132 via a bonding wire 162. The circuit device 3 of the peak amplifier 2B receives a second signal through the wiring 122. The second signal and the first signal are signals which are divided from a single signal and have a phase difference therebetween.

The transistor 4 is a first stage amplifying part. A control terminal (a gate) of the transistor 4 is electrically connected to the circuit device 3 via a bonding wire 25. The transistor 4 of the main amplifier 2A receives the first signal from the circuit device 3 of the main amplifier 2A and amplifies the first signal. The transistor 4 of the peak amplifier 2B receives the second signal from the circuit device 3 of the peak amplifier 2B and amplifies the second signal.

The circuit device 5 is a circuit for matching the input impedance of the transistor 6. The circuit device 5 of the main amplifier 2A is electrically connected to a current terminal (a drain) of the transistor 4 of the main amplifier 2A via a bonding wire 26. The circuit device 5 of the main amplifier 2A receives the amplified first signal from the transistor 4 of the main amplifier 2A. The circuit device 5 of the peak amplifier 2B is electrically connected to a current terminal (a drain) of the transistor 4 of the peak amplifier 2B via a bonding wire 26. The circuit device 5 of the peak amplifier 2B receives the amplified second signal from the transistor 4 of the peak amplifier 2B.

The transistor 6 is a second stage amplifying part. A control terminal (a gate) of the transistor 6 is electrically connected to the circuit device 5 via a bonding wire 27. The transistor 6 of the main amplifier 2A receives the amplified first signal from the circuit device 5 of the main amplifier 2A and further amplifies the amplified first signal. A current terminal (a drain) of the transistor 6 of the main amplifier 2A is electrically connected to the pad 133 via a bonding wire 163. The first signal amplified by the transistor 6 of the main amplifier 2A is output to the outside of the Doherty amplifier 1 through the wiring 123. The transistor 6 of the peak amplifier 2B receives the amplified second signal from the circuit device 5 of the peak amplifier 2B and further amplifies the amplified second signal. A current terminal (a drain) of the transistor 6 of the peak amplifier 2B is electrically connected to the pad 134 via a bonding wire 164. The second signal amplified by the transistor 6 of the peak amplifier 2B is output to the outside of the Doherty amplifier 1 through the wiring 124. The first signal and the second signal output from the Doherty amplifier 1 are combined with each other on the outside of the Doherty amplifier 1.

The circuit device 5 of the main amplifier 2A is connected to the pad 135 via a bonding wire 165. A first bias voltage is input to the circuit device 5 through the wiring 125. The circuit device 5 of the main amplifier 2A is connected to the pad 136 via a bonding wire 166. A second bias voltage is input to the circuit device 5 through the wiring 126.

The circuit device 5 of the peak amplifier 2B is connected to the pad 137 via a bonding wire 167. A first bias voltage is input to the circuit device 5 through the wiring 127. The circuit device 5 of the peak amplifier 2B is connected to the pad 138 via a bonding wire 168. A second bias voltage is input to the circuit device 5 through the wiring 128.

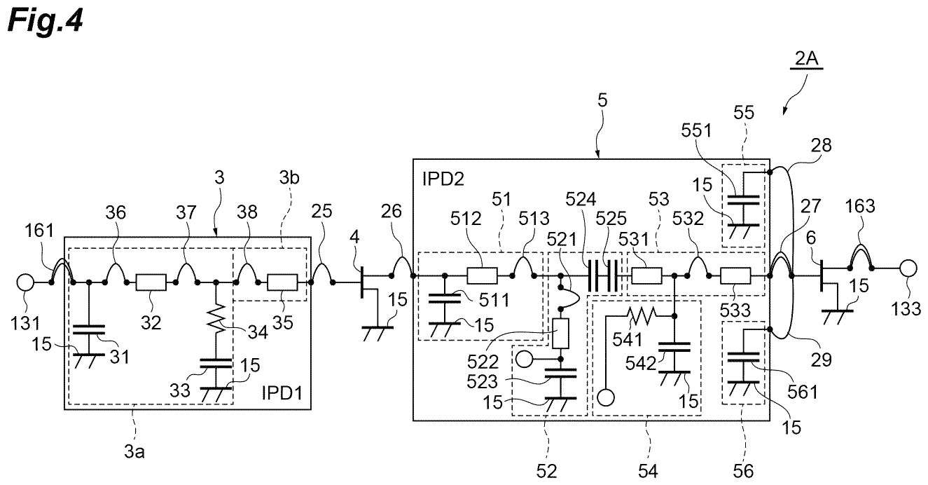

FIG. 4 is a circuit diagram of the main amplifier 2A. The circuit device 3 and the circuit device 5 of the peak amplifier 2B have the same configuration as those of the main amplifier 2A, except for a resistance values of a resistor and a capacitance value of a capacitor. However, the circuit device 3 and the circuit device 5 of the peak amplifier 2B have structures that are linearly symmetrical to the circuit device 3 and the circuit device 5 of the main amplifier 2A, respectively. As shown in FIG. 4, the circuit device 3 includes a low-pass filter 3a and a delay line 3b.

The low-pass filter 3a is a so-called x-type low-pass filter and includes a capacitor 31, a transmission line 32, a capacitor 33, a resistor 34, and bonding wires 36 and 37. The bonding wire 36, the transmission line 32, and the bonding wire 37 constitute a signal transmission line through which the first signal (in the case of the peak amplifier 2B, the second signal) is transmitted and are connected in series in that order between the bonding wire 161 (the bonding wire 162 in the case of the peak amplifier 2B) and the delay line 3b. That is, the bonding wire 36 is interposed between an input end of the low-pass filter 3a and the transmission line 32, and the bonding wire 37 is interposed between the transmission line 32 and an output end of the low-pass filter 3a. The capacitors 31 and 33 function as bypass capacitors for the first signal (in the case of the peak amplifier 2B, the second signal). A first electrode of the capacitor 31 is connected to a node between the bonding wire 161 (in the case of the peak amplifier 2B, the bonding wire 162) and the bonding wire 36 (that is, the input end of the low-pass filter 3a). A second electrode of the capacitor 31 is connected to the reference potential pattern 15. A first electrode of the capacitor 33 is connected to a node between the bonding wire 37 and the delay line 3b (that is, the output end of the low-pass filter 3a) via the resistor 34. A second electrode of the capacitor 33 is connected to the reference potential pattern 15.

In this way, the bonding wires 36 and 37 constitute a part of the low-pass filter 3a. In other words, first ends of the bonding wires 36 and 37 are connected to the input end of the low-pass filter 3a, and second ends of the bonding wires 36 and 37 are connected to the output end of the low-pass filter 3a. The bonding wires 36 and 37 are completed on a main surface 30a and do not extend beyond an area on the main surface 30a.

The delay line 3b includes a transmission line 35 and a bonding wire 38. The transmission line 35 and the bonding wire 38 form the signal transmission line and are connected in series with each other between the output end of the low-pass filter 3a and the bonding wire 25. The bonding wire 38 is interposed between the output end of the low-pass filter 3a and the transmission line 35. In this way, the bonding wire 38 constitutes a part of the delay line 3b. The bonding wire 38 is completed on the main surface 30a and does not extend beyond the area on the main surface 30a.

As shown in FIG. 4, the circuit device 5 includes a low-pass filter 51, a high-pass filter 52, a delay line 53, a bias circuit 54, and harmonic processing circuits 55 and 56.

The low-pass filter 51 is a so-called L-type low-pass filter and includes a capacitor 511, a transmission line 512, and a bonding wire 513. The transmission line 512 and the bonding wire 513 constitute the signal transmission line and are connected in series with each other between the bonding wire 26 and the high-pass filter 52. That is, the bonding wire 513 is interposed between the transmission line 512 and an output end of the low-pass filter 51. The bonding wire 513 is completed on a main surface 50a and does not extend beyond an area on the main surface 50a. The capacitor 511 functions as a bypass capacitor. A first electrode of the capacitor 511 is connected to a node between the bonding wire 26 and the transmission line 512 (that is, an input end of the low-pass filter 51). A second electrode of the capacitor 511 is connected to the reference potential pattern 15.

The high-pass filter 52 includes a bonding wire 521, a transmission line 522, and capacitors 523, 524, and 525. The capacitors 524 and 525 are provided on the signal transmission line and function as coupling capacitors. The capacitors 524 and 525 are connected in series with each other between the low-pass filter 51 and the delay line 53. The bonding wire 521, the transmission line 522, and the capacitor 523 are connected in series in that order between a node between the low-pass filter 51 and the capacitor 524 (that is, an input end of the high-pass filter 52) and the reference potential pattern 15. That is, the bonding wire 521 is interposed between the input end of the high-pass filter 52 and the transmission line 522. The bonding wire 521 is completed on the main surface 50a and does not extend beyond the area on the main surface 50a. The first bias voltage is input to the node between the transmission line 522 and the capacitor 523 from the pad 135 via the bonding wire 165 (see FIGS. 2 and 3) (in the case of the peak amplifier 2B, from the pad 137 via the bonding wire 167). In this way, the bonding wire 521 constitutes a part of a bias wiring provided in the high-pass filter 52. The capacitor 523 functions as a bypass capacitor for the first bias voltage.

The delay line 53 includes a bonding wire 532 and transmission lines 531 and 533. The transmission line 531, the bonding wire 532, and the transmission line 533 constitute the signal transmission line and are connected in series in that order between an output end of the high-pass filter 52 and the bonding wire 27. That is, the bonding wire 532 is interposed between transmission line 531 and the transmission line 533. The bonding wire 532 is completed on the main surface 50a and does not extend beyond the area on the main surface 50a.

The bias circuit 54 includes a resistor 541 and a capacitor 542. A first end of the resistor 541 is connected to a node between the transmission line 531 and the bonding wire 532. A second end of the resistor 541 is connected to the pad 136 via the bonding wire 166 (see FIGS. 2 and 3) and receives the second bias voltage from the pad 136 (in the case of the peak amplifier 2B, receives the second bias voltage from the pad 138 via the bonding wire 168). The capacitor 542 functions as a bypass capacitor for the second bias voltage. A first electrode of the capacitor 542 is connected to the node between the transmission line 531 and the bonding wire 532. A second electrode of the capacitor 542 is connected to the reference potential pattern 15.

The harmonic processing circuit 55 includes a capacitor 551. The harmonic processing circuit 56 includes a capacitor 561. First electrodes of the capacitors 551 and 561 are connected to a node between the bonding wire 27 and the control terminal (the gate) of the transistor 6 via the bonding wires 28 and 29, respectively. Second electrodes of the capacitors 551 and 561 are connected to the reference potential pattern 15. The harmonic processing circuits 55 and 56 remove a harmonic component from the first signal (in the case of the peak amplifier 2B, the second signal) input to the transistor 6.

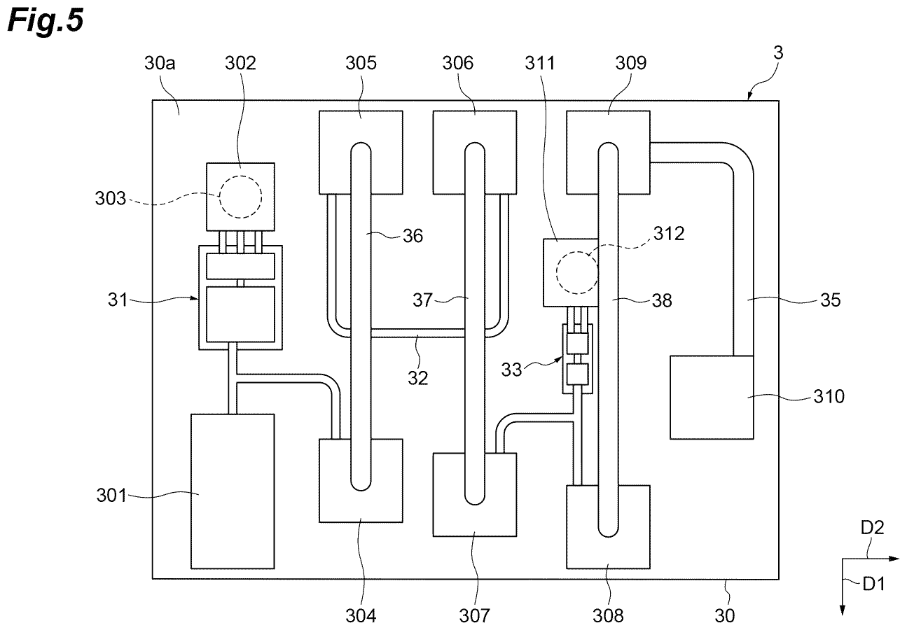

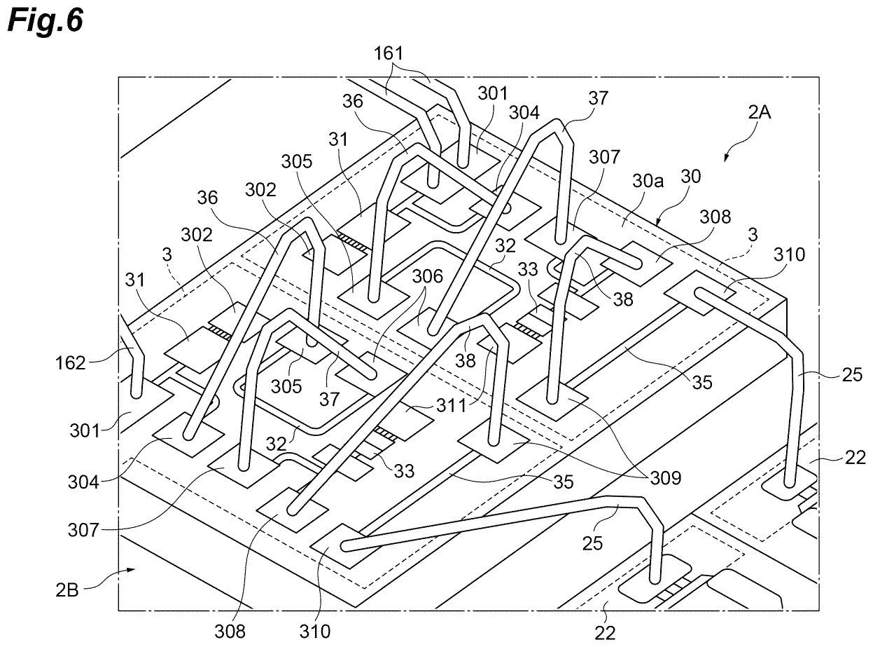

FIG. 5 is a plan view of the circuit device 3. FIG. 6 is a perspective view of the circuit device 3. As shown in FIGS. 5 and 6, the circuit device 3 includes a substrate 30 having the main surface 30a. The elements of the low-pass filter 3a and the delay line 3b described above are disposed on the main surface 30a. In addition, pads 301, 302, 304 to 311 are provided on the main surface 30a. The pads 301, 304, 307, 308, and 310 are disposed side by side in the direction D2 in an area near one end of the main surface 30a in the direction D1. The pads 302, 305, 306, and 309 are disposed side by side in the direction D2 in an area near the other end of the main surface 30a in the direction D1.

One end of the bonding wire 161 (in the case of the peak amplifier 2B, the bonding wire 162) is fixed to the pad 301. The first electrode of the capacitor 31 is connected to the pad 301 via the wiring provided on the main surface 30a, and the second electrode of the capacitor 31 is connected to the pad 302. The pad 302 is connected to the reference potential pattern 15 (not shown) through a via 303 that passes through the substrate 30 in a thickness direction. The pad 304 is connected to a node between the pad 301 and the capacitor 31 via the wiring provided on the main surface 30a.

The pad 305 and the pad 306 are connected to each other via the transmission line 32 provided on the main surface 30a. The first end of the bonding wire 36 is fixed to the pad 304, and the second end of the bonding wire 36 is fixed to the pad 305. The first end of the bonding wire 37 is fixed to the pad 306, and the second end of the bonding wire 37 is fixed to the pad 307. The bonding wires 36 and 37 extend in the direction D1 in a plan view and straddle the transmission line 32. The bonding wire 37 is arranged side by side with the bonding wire 36 in the direction D2.

The pad 308 is connected to the pad 307 via the wiring provided on the main surface 30a. The first electrode of the capacitor 33 is connected to a node between the pad 307 and the pad 308. The second electrode of the capacitor 33 is connected to the pad 311. The pad 311 is connected to the reference potential pattern 15 (not shown) through a via 312 that passes through the substrate 30 in the thickness direction. A first end of the bonding wire 38 is fixed to the pad 308, and a second end of the bonding wire 38 is fixed to the pad 309. The bonding wire 38 extends in the direction D1 in a plan view and straddles the pad 311. The pad 309 is connected to the pad 310 via the transmission line 35 provided on the main surface 30a. One end of the bonding wire 25 is fixed to the pad 310.

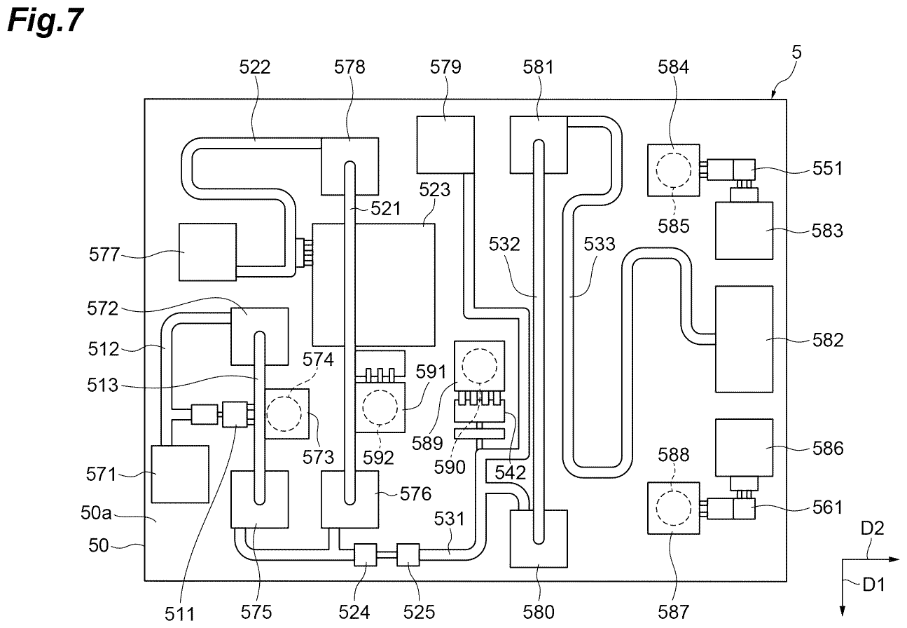

FIG. 7 is a plan view of the circuit device 5. As shown in FIG. 7, the circuit device 5 includes a substrate 50 having the main surface 50a. The elements of the low-pass filter 51, the high-pass filter 52, the delay line 53, the bias circuit 54, and the harmonic processing circuits 55 and 56 described above are disposed on the main surface 50a. In addition, pads 571 to 573, 575 to 584, 586, and 587 are provided on the main surface 50a. The pads 571, 575, 576, 580, and 587 are disposed side by side in the direction D2 in an area near one end of the main surface 50a in the direction D1. The pads 578, 579, 581, and 584 are disposed side by side in the direction D2 in an area near the other end of the main surface 50a in the direction D1.

One end of the bonding wire 26 (see FIGS. 2 to 4) is fixed to the pad 571. The first electrode of the capacitor 511 is connected to the pad 571 via the wiring provided on the main surface 50a, and the second electrode of the capacitor 511 is connected to the pad 573. The pad 573 is connected to the reference potential pattern 15 (not shown) through a via 574 that passes through the substrate 50 in the thickness direction. The pad 572 is connected to a node between the pad 571 and the capacitor 511 via the wiring provided on the main surface 50a. A first end of the bonding wire 513 is fixed to the pad 572, and a second end of the bonding wire 513 is fixed to the pad 575. The bonding wire 513 extends in the direction D1 in a plan view and straddles the pad 573.

The pad 575 is connected to the pad 576 via the wiring provided on the main surface 50a. A first end of the bonding wire 521 is fixed to the pad 576, and a second end of the bonding wire 521 is fixed to the pad 578. The bonding wire 521 extends in the direction D1 in a plan view and is arranged side by side with the bonding wire 513 in the direction D2. The pad 578 is connected to the pad 577 via the transmission line 522 provided on the main surface 50a. One end of the bonding wire 165 (in the case of the peak amplifier 2B, the bonding wire 167) shown in FIGS. 2 to 4 is fixed to the pad 577, and the pad 577 receives the first bias voltage. A first electrode of the capacitor 523 is connected to a node between the pad 577 and the pad 578. A second electrode of the capacitor 523 is connected to a pad 591. The pad 591 is connected to the reference potential pattern 15 through a via 592 that passes through the substrate 50 in the thickness direction. The bonding wire 521 straddles the capacitor 523 and the pad 591.

The pad 580 is connected to a node between the pad 575 and the pad 576 via the capacitor 524, the capacitor 525, and the transmission line 531 provided on the main surface 50a. The pad 579 is connected to a node between the transmission line 531 and the pad 580 via the wiring provided on the main surface 50a. One end of the bonding wire 166 (in the case of the peak amplifier 2B, the bonding wire 168) shown in FIGS. 2 to 4 is fixed to the pad 579, and the pad 579 receives the second bias voltage. A first electrode of the capacitor 542 is connected to a node between the pad 580 and the pad 579. A second electrode of the capacitor 542 is connected to a pad 589. The pad 589 is connected to the reference potential pattern 15 through a via 590 that passes through the substrate 50 in the thickness direction.

A first end of the bonding wire 532 is fixed to the pad 580, and a second end of the bonding wire 532 is fixed to the pad 581. The bonding wire 532 extends in the direction D1 in a plan view and is in close proximity to a wiring connecting the pad 580 and the pad 579 in a plan view. The shortest distance between the wiring connecting the pad 580 and the 579 and the bonding wire 532 in a plan view is shorter than a distance between the wirings provided on the main surface 50a. The bonding wire 532 is aligned with the bonding wires 521 and 513 in the direction D2.

The pad 582 is connected to the pad 581 via the transmission line 533 provided on the main surface 50a. The transmission line 533 is bent several times on the main surface 50a in order to ensure a sufficient length for impedance matching. One end of the bonding wire 27 shown in FIGS. 2 to 4 is fixed to the pad 582.

One ends of the bonding wires 28 and 29 shown in FIG. 4 are fixed to the pads 583 and 586, respectively. The first electrodes of the capacitors 551 and 561 are connected to the pads 583 and 586, respectively. The second electrodes of the capacitors 551 and 561 are connected to the pads 584 and 587, respectively. The pads 584 and 587 are connected to the reference potential pattern 15 through vias 585 and 588 that pass through the substrate 50 in the thickness direction, respectively.

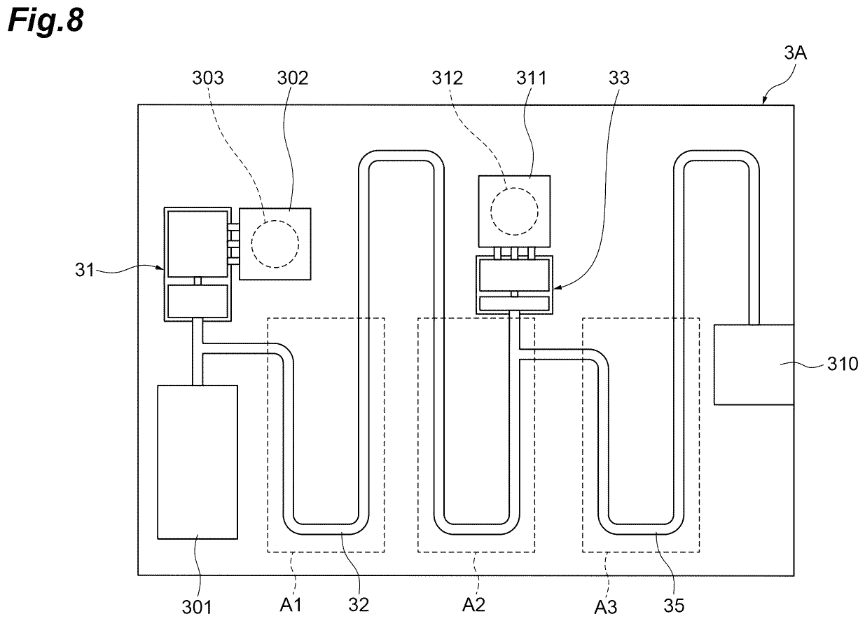

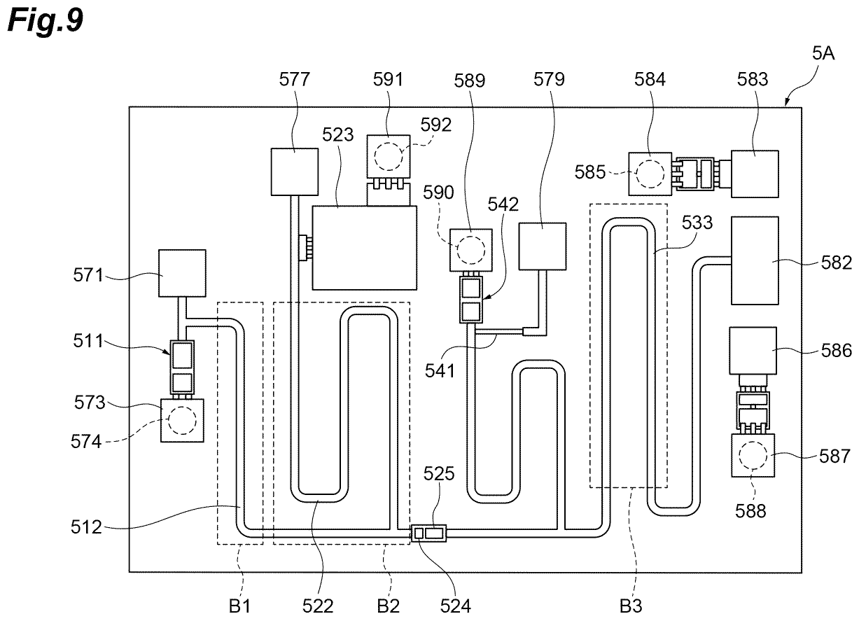

The effects obtained by the circuit devices 3 and 5 of the present embodiment described above will be described together with the problems of a circuit device of a comparative example. FIG. 8 is a plan view showing a circuit device 3A according to the comparative example. This circuit device 3A differs from the circuit device 3 of the present embodiment in the following points. That is, the circuit device 3A does not include the bonding wires 36, 37, and 38, and the pad 301, the pad 310, the capacitor 31, and the capacitor 33 are connected to each other via the wiring provided on the main surface 30a. In addition, FIG. 9 is a plan view showing a circuit device 5A according to the comparative example. This circuit device 5A differs from the circuit device 5 of the present embodiment in the following points. That is, the circuit device 5A does not include the bonding wires 513, 521, 532, and the pad 571, the pad 577, the pad 579, the pad 582, the capacitor 511, and the capacitor 542 are connected to each other via the wiring provided on the main surface 50a.

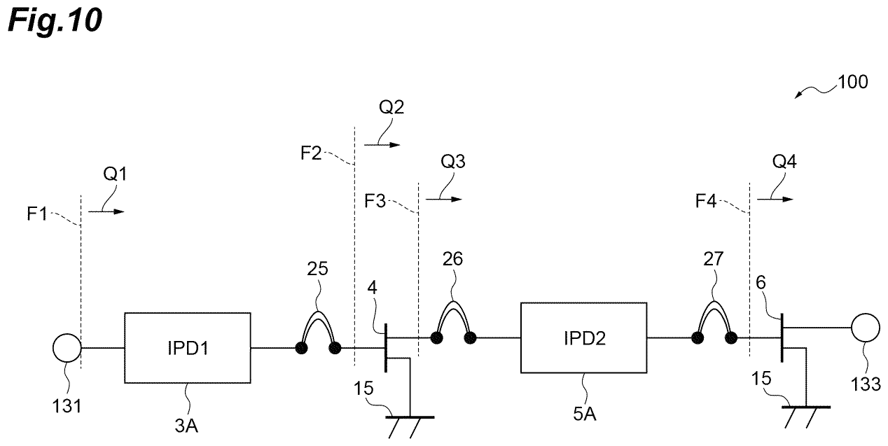

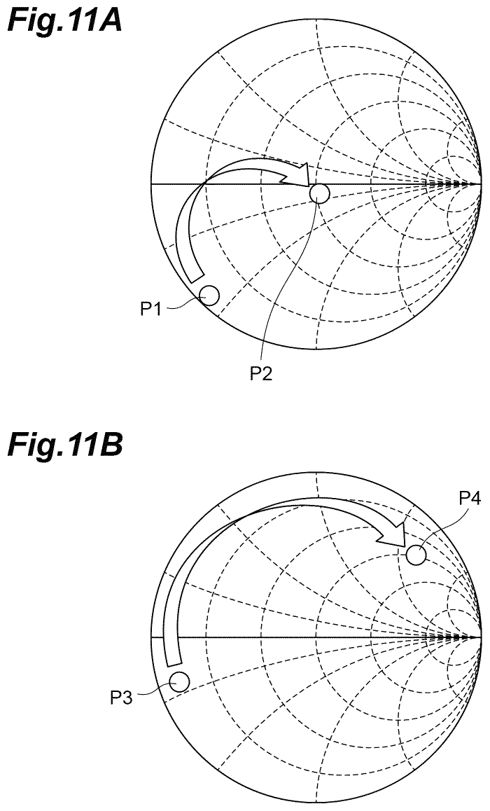

FIG. 10 is a diagram showing a simplified configuration of a main amplifier 100 of a Doherty amplifier including the circuit devices 3A and 5A. When designing the main amplifier 100, (1) it is important that the impedance when viewed in a direction of an arrow Q1 from a position F1 be close to the impedance of the transistor 4 (that is, S11) when viewed in a direction of an arrow Q2 from a position F2. Furthermore, (2) it is important that the load impedance of the transistor 4 when viewed in a direction of an arrow Q3 from a position F3 be close to the impedance of the transistor 6 (that is, S11) when viewed in a direction of an arrow Q4 from a position F4. Parts (a) and (b) of FIG. 11 are Smith charts relating to the above (1) and (2), respectively. In the part (a) of FIG. 11, a plot P1 represents S11 of the transistor 4 at the position F2, and a plot P2 represents the impedance at the position F1. In the part (b) of FIG. 11, a plot P3 represents S11 of the transistor 6 at the position F4, and a plot P4 represents the impedance at the position F3. The circuit device 3A brings the plot P1 shown in the part (a) of FIG. 11 closer to the plot P2. The circuit device 5A brings the plot P3 shown in the part (b) of FIG. 11 closer to the plot P4. Typically, the magnitude of the signal amplified by the transistor 6, which is a second stage transistor, is greater than the magnitude of the signal amplified by the transistor 4, which is a first stage transistor. Therefore, a moving distance from the plot P3 to the plot P4 is longer than a moving distance from the plot P1 to the plot P2. The longer the moving distance, the longer the transmission line in a matching circuit becomes, leading to an increase in size of the matching circuit. The increase in size of the matching circuit leads to an increase in size of the Doherty amplifier.

To address such a problem, the circuit device 3 of the present embodiment has the bonding wires 36, 37, and 38 that serve as internal wirings of the matching circuit and are completed on the main surface 30a. The bonding wires 36, 37, and 38 replace wiring portions A1, A2, and A3 shown in FIG. 8, respectively. In addition, the circuit device 5 of the present embodiment has the bonding wires 513, 521, and 532 that serve as internal wirings of the matching circuit and are completed on the main surface 50a. The bonding wires 513, 521, and 532 replace wiring portions B1, B2, and B3 shown in FIG. 9, respectively.

Compared to the transmission line, the bonding wire can be disposed close to other elements that constitute the matching circuit (other portions of the transmission line, the capacitor, and the like) in a planar view, or can straddle the other elements. Therefore, even in a case in which the transmission line is long, the area required for laying out the transmission line can be reduced by replacing a part of the transmission line with the bonding wire. Therefore, according to the circuit devices 3 and 5 of the present embodiment, the circuit devices 3 and 5 can be made smaller in size even in a case in which when the transmission line is long.

As in the present embodiment, the bonding wires 36, 37, 38, 513, 521, and 532 may straddle the other elements included in the matching circuit. In this case, since the space above the other elements is utilized, the area for laying out the transmission line can be made smaller, and the circuit devices 3 and 5 can be made even smaller in size.

As in the present embodiment, the matching circuit may have the filters (the low-pass filter 3a, the low-pass filter 51, and the high-pass filter 52), and the bonding wires 36, 37, 513, and 521 may constitute a part of the filters. In this case, since the area on the main surface 30a (or 50a) required for the filter can be reduced, the circuit devices 3 and 5 can be made smaller in size.

As in the present embodiment, the matching circuit may have the delay lines 3b and 53, and the bonding wires 38 and 532 may constitute a part of the delay lines. In this case, since the area on the main surface 30a (or 50a) required for the delay line can be reduced, the circuit devices 3 and 5 can be made smaller in size.

As in the present embodiment, the matching circuit may have the transmission lines 32, 35, 512, 522, 531, and 533, and each of the bonding wires 36, 37, 38, 513, 521, and 532 may be connected in series with any of these transmission lines 32, 35, 512, 522, 531, and 533. In this way, by connecting the bonding wire in series with the transmission line, it is possible to replace another transmission line connected to the transmission line, that is, a part of the transmission line, with the bonding wire. Therefore, the area required for laying out the transmission line can be reduced.

[Modification example] In the embodiment described above, the extending directions of the bonding wires 36, 37, 38, 513, 521, and 532 of the main amplifier 2A in a plan view are aligned with the extending directions of the bonding wires 36, 37, 38, 513, 521, and 532 of the peak amplifier 2B in a plan view. The present invention is not limited to this form, and the extending directions of the bonding wires 36, 37, 38, 513, 521, and 532 in a plan view may be different between the main amplifier 2A and the peak amplifier 2B.

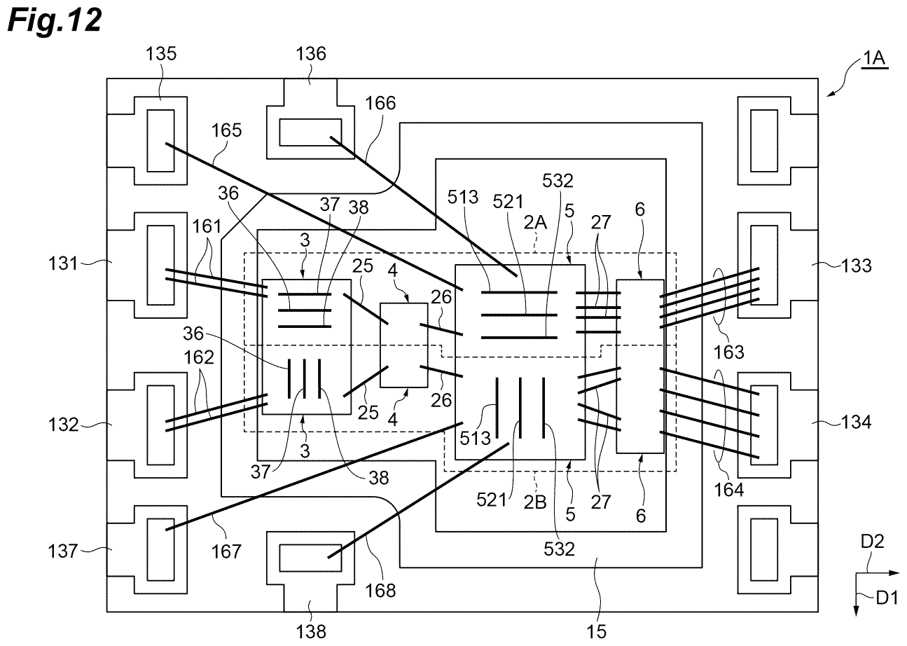

FIG. 12 is a plan view showing a Doherty amplifier 1A as an example. In FIG. 12, when viewed in the normal direction of the main surface 30a, the bonding wires 36, 37, and 38 of the circuit device 3 (a first circuit device) of the main amplifier 2A extend in the direction D2 in a plan view. On the other hand, when viewed in the normal direction of the main surface 30a, the bonding wires 36, 37, and 38 of the circuit device 3 (a second circuit device) of the peak amplifier 2B extend in the direction D1 in a plan view. For example, in this way, the extending directions of the bonding wires 36, 37, and 38 of the circuit device 3 of the main amplifier 2A when viewed in the normal direction of the main surface 30a may intersect with the extending directions of the bonding wires 36, 37, and 38 of the circuit device 3 of the peak amplifier 2B when viewed in the same direction. In this case, the crosstalk between the circuit device 3 of the main amplifier 2A and the circuit device 3 of the peak amplifier 2B can be reduced.

Similarly, in FIG. 12, when viewed in the normal direction of the main surface 50a, the bonding wires 513, 521, and 532 of the circuit device 5 (a first circuit device) of the main amplifier 2A extend in the direction D2 in a plan view. On the other hand, when viewed in the normal direction of the main surface 50a, the bonding wires 513, 521, and 532 of the circuit device 5 (a second circuit device) of the peak amplifier 2B extend in the direction D1 in a plan view. For example, in this way, the extending directions of the bonding wires 513, 521, and 532 of the circuit device 5 of the main amplifier 2A when viewed in the normal direction of the main surface 50a may intersect with the extending directions of the bonding wires 513, 521, and 532 of the circuit device 5 of the peak amplifier 2B when viewed in the same direction. In this case, the crosstalk between the circuit device 5 of the main amplifier 2A and the circuit device 5 of the peak amplifier 2B can be reduced.

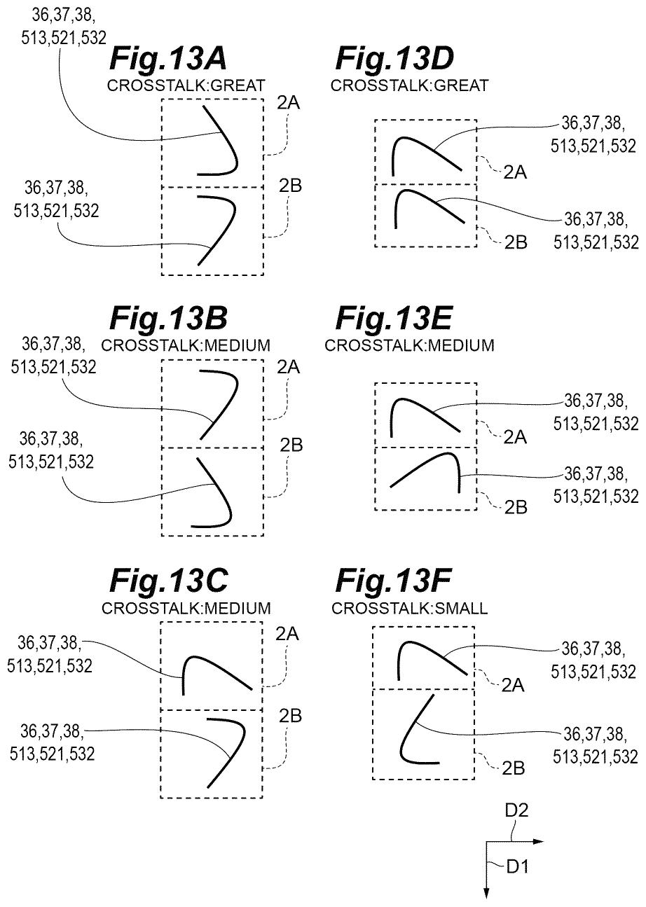

Parts (a) to (f) of FIG. 13 are diagrams schematically showing a variation of a relationship between the extending directions of the bonding wires 36, 37, 38, 513, 521, and 532 of the circuit devices 3 and 5 of the main amplifier 2A and the extending directions of the bonding wires 36, 37, 38, 513, 521, and 532 of the circuit devices 3 and 5 of the peak amplifier 2B. The parts (a) and (b) of FIG. 13 show a case in which the extending directions of the bonding wires 36, 37, 38, 513, 521, and 532 of the main amplifier 2A and the peak amplifier 2B are all in the direction D1. The parts (d) and (e) of FIG. 13 show a case in which the extending directions of the bonding wires 36, 37, 38, 513, 521, and 532 of the main amplifier 2A and the peak amplifier 2B are all in the direction D2. The parts (c) and (f) of FIG. 13 show a case in which the extending directions of the bonding wires 36, 37, 38, 513, 521, and 532 of one of the main amplifier 2A and the peak amplifier 2B are in the direction D2 and the extending directions of the bonding wires 36, 37, 38, 513, 521, and 532 of the other of the main amplifier 2A and the peak amplifier 2B are in the direction D1.

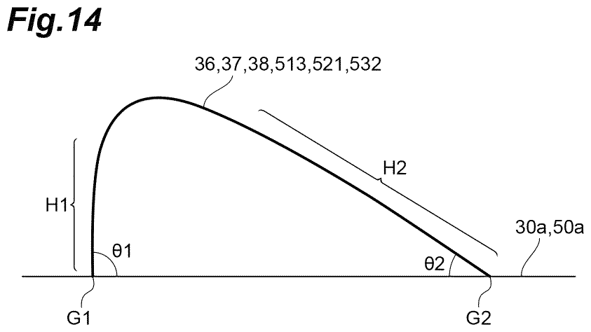

FIG. 14 is a side view of each of the bonding wires 36, 37, 38, 513, 521, and 532. As shown in FIG. 14, the bonding wires 36, 37, 38, 513, 521, and 532 each have a starting end G1 and a finishing end G2. The starting end G1 is a portion at which the bonding wire starts, and the finishing end G2 is a portion at which the bonding wire finishes. The bonding wires 36, 37, 38, 513, 521, and 532 each have a portion H1 that includes the starting end G1 and a portion H2 that includes the finishing end G2. An inclination angle θ1 of the portion H1 with respect to the main surface 30a (or 50a) is larger than an inclination angle θ2 of the portion H2 with respect to the main surface 30a (or 50a).

FIG. 13 is referred to again. In the form shown in the part (a) of FIG. 13, the bonding wires 36, 37, 38, 513, 521, and 532 of the main amplifier 2A are formed such that the portion H1 with a large inclination angle is closer to the peak amplifier 2B than the portion H2 with a small inclination angle. Similarly, the bonding wires 36, 37, 38, 513, 521, and 532 of the peak amplifier 2B are formed such that the portion H1 with a large inclination angle is closer to the main amplifier 2A than the portion H2 with a small inclination angle. In this case, the bonding wires of the main amplifier 2A and the bonding wires of the peak amplifier 2B are parallel to each other while being close to each other over a long distance, and thus the crosstalk between the main amplifier 2A and the peak amplifier 2B is large.

In addition, in the form shown in the part (b) of FIG. 13, the bonding wires 36, 37, 38, 513, 521, and 532 of the main amplifier 2A are formed such that the portion H2 with a small inclination angle is closer to the peak amplifier 2B than the portion H1 with a large inclination angle. Similarly, the bonding wires 36, 37, 38, 513, 521, and 532 of the peak amplifier 2B are formed such that the portion H2 with a small inclination angle is closer to the main amplifier 2A than the portion H1 with a large inclination angle. In this case, the bonding wires of the main amplifier 2A and the bonding wires of the peak amplifier 2B are not parallel to each other, and thus the crosstalk between the main amplifier 2A and the peak amplifier 2B is reduced compared to the form of the part (a) of FIG. 13. However, since the extending directions of the bonding wires are the same between the main amplifier 2A and the peak amplifier 2B, some crosstalk occurs.

In the form shown in the part (d) of FIG. 13, the orientations of the portions H2 relative to the portions H1 in the direction D2 are aligned with each other between the main amplifier 2A and the peak amplifier 2B. In this case, the bonding wires of the main amplifier 2A and the bonding wires of the peak amplifier 2B are parallel to each other over a long distance, and thus the crosstalk between the main amplifier 2A and the peak amplifier 2B is large.

In the form shown in the part (e) of FIG. 13, the orientations of the portions H2 relative to the portions H1 in the direction D2 are opposite to each other between the main amplifier 2A and the peak amplifier 2B. In this case, the bonding wires of the main amplifier 2A and the bonding wires of the peak amplifier 2B are not parallel to each other, and thus the crosstalk between the main amplifier 2A and the peak amplifier 2B is reduced compared to the form of the part (d) of FIG. 13. However, since the extending directions of the bonding wires are the same between the main amplifier 2A and the peak amplifier 2B, some crosstalk occurs.

In the form shown in the part (c) of FIG. 13, the bonding wires 36, 37, 38, 513, 521, and 532 of the peak amplifier 2B are formed such that the portion H1 with a large inclination angle is closer to the main amplifier 2A than the portion H2 with a small inclination angle. However, in the form shown in part (c) of FIG. 13, the extending directions of the bonding wires of the main amplifier 2A and the extending directions of the bonding wires of the peak amplifier 2B intersect with each other, and thus, even if the portion H1 of each of the bonding wires of the peak amplifier 2B is disposed close to the main amplifier 2A, the crosstalk between the main amplifier 2A and the peak amplifier 2B is reduced compared to the forms of the parts (a) and (d) of FIG. 13.

In the form shown in the part (f) of FIG. 13, the bonding wires 36, 37, 38, 513, 521, and 532 of the peak amplifier 2B are formed such that the portion H2 with a small inclination angle is closer to the main amplifier 2A than the portion H1 with a large inclination angle. In this way, by moving the portion Hl with a large inclination angle away from the main amplifier 2A, the crosstalk between the main amplifier 2A and the peak amplifier 2B is further reduced. That is, the form shown in the part (f) of FIG. 13 is a form that can most effectively reduce the crosstalk between the main amplifier 2A and the peak amplifier 2B.

As shown in the part (f) of FIG. 13, in a case in which the bonding wires of the circuit devices 3 and 5 of the main amplifier 2A are along the direction D2 and the bonding wires of the circuit devices 3 and 5 of the peak amplifier 2B are along the direction D1, in the bonding wires of the circuit devices 3 and 5 of the peak amplifier 2B, the portion H2 with a smaller inclination angle may be located close to the bonding wires of the main amplifier 2A and the portion H1 with a larger inclination angle may be located away from the bonding wires of the main amplifier 2A. In this case, the crosstalk between the circuit devices 3 and 5 of the main amplifier 2A and the circuit devices 3 and 5 of the peak amplifier 2B can be further reduced.

What is claimed is:

1. A circuit device for impedance matching with a transistor, comprising:
a substrate having a main surface; and
a matching circuit provided on the main surface and connected to an input terminal or an output terminal of the transistor to perform impedance matching with the transistor,
wherein the matching circuit has a bonding wire that serves as an internal wiring of the matching circuit and is completed on the main surface.

2. The circuit device according to claim 1, wherein the bonding wire straddles other elements included in the matching circuit.

3. The circuit device according to claim 1,
wherein the matching circuit has a filter, and
wherein the bonding wire constitutes a part of the filter.

4. The circuit device according to claim 3,
wherein the filter is a low-pass filter, and
wherein a first end of the bonding wire is connected to an input end of the low-pass filter, and a second end of the bonding wire is connected to an output end of the low-pass filter.

5. The circuit device according to claim 3,
wherein the filter is a high-pass filter, and
wherein the bonding wire constitutes a part of a bias wiring provided in the high-pass filter.

6. The circuit device according to claim 1,
wherein the matching circuit has a delay line, and
wherein the bonding wire constitutes a part of the delay line.

7. The circuit device according to claim 1,
wherein the matching circuit has a transmission line, and
wherein the bonding wire is connected in series with the transmission line.

8. A Doherty amplifier including a main amplifier and a peak amplifier comprising:
a substrate having a main surface;
a matching circuit provided on the main surface and connected to an input terminal or an output terminal of a transistor to perform impedance matching with the transistor, the matching circuit has a bonding wire that serves as an internal wiring of the matching circuit and is completed on the main surface, the main amplifier including the matching circuit as a first circuit device,
the peak amplifier including a second matching circuit as a second circuit device,
wherein the first circuit device is disposed side by side with the second circuit device in a first direction, and
wherein an extending direction of the bonding wire of the first circuit device when viewed in a normal direction of the main surface intersects with an extending direction of the bonding wire of the second circuit device when viewed in the normal direction.

9. The Doherty amplifier according to claim 8,
wherein one bonding wire of the bonding wire of the first circuit device and the bonding wire of the second circuit device is along the first direction,
wherein another bonding wire of the bonding wire of the first circuit device and the bonding wire of the second circuit device is along a second direction intersecting with the first direction,
wherein the one bonding wire includes a first portion close to the another bonding wire and a second portion further away from the another bonding wire than the first portion, and
wherein an inclination angle of the second portion with respect to the main surface is greater than an inclination angle of the first portion with respect to the main surface.
